(19) United States
(12) Patent Application Publication
(10) Pub. No.: US 2018/0217059 A1
(43) Pub. Date: Aug. 2, 2018

(54) SEGMENTED DETECTOR FOR A CHARGED PARTICLE BEAM DEVICE

(71) Applicant: FEI Company, Hillsboro, OR (US)

(72) Inventors: Nicholas C. BARBI, Sarasota, FL (US); Richard B. MOTT, Ringoes, NJ (US); Owen HEALY, Philadelphia, PA (US)

(21) Appl. No.: 15/749,043

(22) PCT Filed: Jul. 22, 2016
(86) PCT No.: PCT/US16/43507

§ 371 Date: Jan. 30, 2018

Related U.S. Application Data
(60) Provisional application No. 62/199,565, filed on Jul. 31, 2015.

(51) Int. Cl. G01N 21/64; H01J 37/244; H01J 37/28; G01J 1/42

(52) U.S. Cl. CPC G01N 21/64; H01J 37/244; H01J 37/28; H01J 2237/24475; H01J 2237/2445; H01J 2237/24465; G01J 1/42

(57) ABSTRACT

A detector for a charged particle beam device includes a substrate, a number of first sensor devices provided on the substrate, wherein the first sensor devices are structured to be sensitive to and generate a first signal in response to electrons ejected by a specimen, and a number of second sensor devices provided on the substrate, wherein the second sensor devices are structured to be sensitive to and generate a second signal in response to photons emitted by the specimen. Also, a photon detector wherein each of the photon sensor devices is structured to be sensitive to and generate a signal in response to photons emitted by the specimen, and wherein each of the photon sensor devices comprises a MultiPixel Photon Counter device. Further, a method of imaging a specimen using a charged particle beam device uses beam blanking and determination of estimated a decay time constants.

### CROSS-REFERENCE TO RELATED APPLICATIONS

This application claims priority under 35 U.S.C. § 119(e) from U.S. provisional patent application No. 62/199,565, entitled “Segmented Detector for a Charged Particle Beam Device” and filed on Jul. 31, 2015, the contents of which are incorporated herein by reference.

### BACKGROUND OF THE INVENTION

### 1. Field of the Invention

The present invention relates to imaging using a charged particle beam device, such as an electron microscope, and, in particular, to a segmented detector for a charged particle beam device including one or more sensors sensitive to electrons and one or more sensors sensitive to photons, and to a charged particle beam device employing such a segmented detector. The present invention also relates to a segmented photon detector employing MultiPixel Photon Counter technology, and to a method of obtaining an image of decay time constants in order to improve cathodoluminescence (CL) imaging.

### 2. Description of the Related Art

An electron microscope (EM) is a type of microscope that uses a particle beam of electrons to illuminate a specimen and produce a magnified image of the specimen. One common type of EM is known as a scanning electron microscope (SEM). An SEM creates images of a specimen by scanning the specimen with a finely focused beam of electrons in a pattern across an area of the specimen, known as a raster pattern. The electrons interact with the atoms that make up the specimen, producing signals that contain information about the specimen's surface topography, composition, and other properties such as crystal orientation and electrical conductivity.

In a typical SEM, electrons are generated by an electron gun assembly that is positioned at the beginning of a series of focusing optics and deflection coils, called an electron column or simply “column” because its axis is typically vertical. The column is followed by a sample chamber or simply “chamber” housing the specimen and accommodating a variety of detectors, probes and manipulators. Because electrons are readily absorbed in air, both the column and the chamber are typically evacuated, although in some cases the chamber may be back-filled to a partial pressure of dry nitrogen or some other gas. After being generated by the electron gun assembly, the electrons follow a path through the column and are caused thereby to form a finely focused beam of electrons (on the order of 1-10 nanometers) that is made to scan the specimen in the chamber in a raster fashion as described above.

When the electron beam hits the specimen, some of the beam electrons (primary electrons) are reflected/ejected back out of the specimen by elastic scattering resulting from collisions between the primary electrons and the nuclei of the atoms of the specimen. These electrons are known as backscattered electrons (BSEs) and provide both atomic number and topographical information about the specimen. Some other primary electrons will undergo inelastic scattering causing secondary electrons (SEs) to be ejected from a region of the specimen very close to the surface, providing an image with detailed topographical information at the highest resolution. If the specimen is sufficiently thin and the incident beam energy sufficiently high, some electrons will pass through the sample (transmitted electrons or TEs). Backscattered and secondary electrons are collected by one or more detectors, which are respectively called a backscattered electron detector (BSED) and a secondary electron detector (SED), which each convert the electrons to an electrical signal used to generate images of the specimen.

Cathodoluminescence (CL) is an optical and electromagnetic phenomenon in which electrons impacting on a luminescent material cause the emission of photons. It is known in the art to fit an SEM as just described with a separate CL detector. In such a configuration, the focused beam of electrons of the SEM impinges the specimen and induces it to emit photons. Those photons are collected by the CL detector and may be used to analyze the internal structure of the specimen in order to get information on the composition, crystal growth and quality of the material.

U.S. Pat. No. 8,410,443 describes a system for collecting both electron and CL images simultaneously. However, the method described therein requires reflection of the visible light away from the electron detector to a separate optical detector. The cover figure of the patent shows the light detectors mounted below the BSE (backscattered electron) detector whose outer surface is mirrored. This arrangement considerably lengthens the minimum working distance (the distance between the pole piece and the sample). Also, mirroring of the BSE detector surface necessarily reduces sensitivity to low-energy electrons, which are absorbed by the mirror coating. Furthermore, the extra optical detector consumes a lot of space around the sample. It is now commonly desirable for other types of detectors to be in close proximity to the sample, so space is at a premium. Space is particularly critical for the dual-beam instruments referenced elsewhere herein. The extra optical detector will also reduce the signal reaching a secondary electron detector, which is a standard imaging mode for electron microscopy.

Thus, there is room for improvement in the field of detectors structured for collection of electron and CL images.

### SUMMARY OF THE INVENTION

In one embodiment, a detector for a charged particle beam device is provided that includes a substrate structured to be mounted within the charged particle beam device, a number of first sensor devices provided on the substrate, wherein each of the first sensor devices is structured to be sensitive to and generate a first signal in response to electrons ejected by a specimen, and a number of second sensor devices provided on the substrate, wherein each of the second sensor devices is structured to be sensitive to and generate a second signal in response to photons emitted by the specimen.

In another embodiment, a photon detector for a charged particle beam device is provided that includes a substrate structured to be mounted within the charged particle beam device, wherein the substrate includes a pass-through extending through the substrate for allowing a beam of the charged particle beam device to pass through the photon detector, and a plurality of photon sensor devices provided on the substrate spaced about the pass-through, wherein each of the photon sensor devices is structured to be sensitive to and generate a signal in response to photons emitted by the specimen, and wherein each of the photon sensor devices comprises a MultiPixel Photon Counter device.

In another embodiment, a method of imaging a specimen using a charged particle beam device is provided. The method includes directing an electron beam of the charged particle beam device to a first pixel position of the specimen for a first period of time, deflecting the electron beam away from the first pixel position for a second period of time, measuring a plurality of light intensity levels emitted from the first pixel position during the second period of time using a detector having a number of MultiPixel Photon Counter sensors, and using the plurality of light intensity levels to estimate a decay time constant for the first pixel position.

In still another embodiment, a charged particle beam device is provided that includes an electron source structured to generate an electron beam, a beam blanker, a photon detector including a number of MultiPixel Photon Counter sensors, and a control system. The control system is structured to cause the electron beam to be directed to a first pixel position of the specimen for a first period of time, cause the beam blanker to deflect the beam away from the first pixel position for a second period of time, cause the detector to measure a plurality of light intensity levels emitted from the first pixel position during the second period of time, and use the plurality of light intensity levels to estimate a decay time constant for the first pixel position.

### BRIEF DESCRIPTION OF THE DRAWINGS

FIG. 1 is a schematic diagram of an SEM according to one exemplary embodiment of the disclosed concept;

FIG. 2 is a schematic diagram of an exemplary EPD that may be used in the SEM of FIG. 1;

FIG. 3 is a processed image of an ore particle agglomerate collected with a prototype of the EPD of FIG. 2;

FIG. 4 is a schematic diagram of an alternative exemplary EPD that may be used in the SEM of FIG. 1;

FIG. 5 is a schematic diagram of another alternative exemplary EPD that may be used in the SEM of FIG. 1;

FIG. 6 is a schematic diagram of an exemplary photon detector that may be used in the SEM of FIG. 1;

FIGS. 7A-7D provide a comparison of standard SED images to CL images captured using a prototype of the EPD of FIG. 2;

FIG. 8 is a schematic representation of an overlay image of an ore particle agglomerate produced in the manner of FIG. 3;

FIG. 9 is a schematic diagram of an SEM according to an alternative exemplary embodiment of the disclosed concept; and

FIG. 10 is a flowchart illustrating a method of obtaining an image of decay time constants according to a further aspect of the disclosed concept.

### DETAILED DESCRIPTION OF EXEMPLARY EMBODIMENTS

As used herein, the singular form of “a”, “an”, and “the” include plural references unless the context clearly dictates otherwise. As used herein, the statement that two or more parts or components are “coupled” shall mean that the parts are joined or operate together either directly or indirectly, i.e., through one or more intermediate parts or components, so long as a link occurs.

As used herein, “directly coupled” means that two elements are directly in contact with each other.

As used herein, “fixedly coupled” or “fixed” means that two components are coupled so as to move as one while maintaining a constant orientation relative to each other.

As used herein, the word “unitary” means a component is created as a single piece or unit. That is, a component that includes pieces that are created separately and then coupled together as a unit is not a “unitary” component or body.

As used herein, the statement that two or more parts or components “engage” one another shall mean that the parts exert a force against one another either directly or through one or more intermediate parts or components.

As used herein, the term “number” shall mean one or an integer greater than one (i.e., a plurality).

As used herein, the term “segmented” in connection with a detector shall mean that the detector includes multiple discrete sensor devices (e.g., on a single substrate) to enable imaging from different viewpoints (elevation and azimuth), wherein the sensor devices have different sensing/detecting characteristics (e.g., one or more sensor devices have a first sensing/detecting characteristic such as the ability to detect electrons or detect light of a first spectral region, and one or more different sensor devices have a second sensing/detecting characteristic such as the ability to detect photons or detect light of a second, different spectral region), and wherein each sensor or type of sensor can be accessed (read out) independently.

As used herein, the terms “solid state photomultiplier” and “MultiPixel Photon Counter (MPPC)” shall mean an array of Geiger mode avalanche photodiodes on a common semiconductor substrate which outputs a current that is proportional to the flux of incident radiation. Current MPPCs are sensitive to photons in the visible (RGB) and near ultraviolet (NUV) regions of the spectrum. In the future, however, there may be MPPCs applicable to infrared or other regions of the spectrum, and it is contemplated that such future MPPCs may be employed in connection with the disclosed concept.

As used herein, the term “silicon photomultiplier (SiPM)” shall mean an MPPC wherein the Geiger mode avalanche photodiodes are formed on a common single silicon substrate.

As used herein, the term “Scintillator-on-photoMultiplier (SoM)” or “SoM sensor” shall mean a device in which a scintillator is intimately coupled to the active surface of an MPPC, such as an SiPM. SoM sensors work in the following way. Electrons reflected or emitted from the sample strike the scintillator, producing multiple photons, the number of which is proportional to the number of electrons of a given energy striking the scintillator. In practice, the electrons hitting the scintillator are predominantly BSEs having energy equal to the SEM accelerating voltage and having intensity strongly related to the local average atomic number (Z) in the region of the sample being impacted by the electron beam at any given time. In turn, the photons generated toward the underlying appropriately-biased MPPC generate a current in the MPPC proportional to their intensity. Thus, at each point in the raster scanned by the incident electron beam, the output from the SoM sensor is proportional to the BSE intensity, and, using appropriate electronics, a BSE image may be produced.

As used herein, the term “bare MPPC” shall mean an MPPC which does not have a scintillator coupled to the active surface thereof (although it may include a non-scintillating coating).

As used herein, the term “bare SiPM” shall mean an SiPM which does not have a scintillator coupled to the active surface thereof (although it may include a non-scintillating coating).

Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

The present invention will now be described, for purposes of explanation, in connection with numerous specific details in order to provide a thorough understanding of the subject invention. It will be evident, however, that the present invention can be practiced without these specific details without departing from the spirit and scope of this innovation.

The disclosed concept provides a charged particle beam device that is able to image both electrons and photons, or measure their intensity, utilizing a single detecting device. As described in greater detail herein, the single detecting device is able to separately and simultaneously detect and image electrons and photons emitted from a sample or target. Examples of charged particle beam devices that may employ the disclosed concept include Electron Microscopes (EMs) as described above, Focused Ion Beam Instruments (FIBs), dual beam instruments, and electron and/or ion beam sample preparation tools.

As described in greater detail herein, a salient characteristic of the disclosed concept is the use of separate and multiple photon and electron sensors in a single, segmented, detector. In the exemplary embodiment described herein, the detector is roughly the same size and thickness as a conventional solid-state backscattered electron detector. In particular, it has a length and width that make it slightly larger than the dimensions of the pole piece of a typical electron microscope, and it has a thickness of between 3 and 6 mm (e.g., between 2 and 5 mm or between 2.5 and 3 mm), which allows a sample to be examined in an SEM at a working distance as small as 8 to 10 mm. Such a detector could use any solid state sensors, provided that one type is sensitive or made sensitive to electrons, while another type is sensitive or made sensitive to photons. Such a detector would allow measurement of electron and photon radiation simultaneously. One particularly advantageous implementation of the detector described herein employs solid MPPC technology, for both the electron and photon segments.

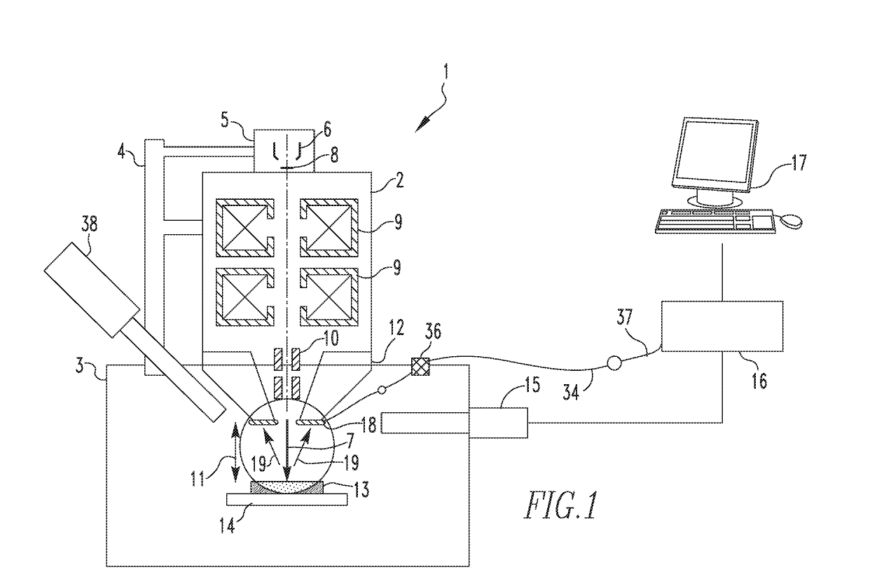

As described below in connection with the exemplary embodiment of FIG. 1, the most common application of the detector according to the disclosed concept is a single annular detector for electron microscopes that is positioned between the exit point of the electron beam in the electron column (the pole piece of the objective lens, for example, in an SEM) and the sample, such that the primary electron beam passes through a hole in the annular detector and the surrounding discrete electron sensors detect electrons, usually but not limited to BSEs, and adjacent discrete photon sensors detect photons emitted from the sample resulting from CL. It should be noted, however, that the light sensors in the detector according to the disclosed concept can detect the presence of any light, regardless of its origin.

FIG. 1 is a schematic diagram of an SEM 1 according to one exemplary embodiment of the disclosed concept. SEM 1 includes an electron column 2, normally positioned vertically, coupled to a sample chamber 3. Electron column 2 and sample chamber 3 may at times herein be referred to collectively as an evacuated housing, being evacuated through a pumping manifold 4. In some cases, the sample chamber 3 may be referred to simply as the “chamber” and the electron column simply as the “column”; when either one is referred to singly, it may also apply to the entire evacuated housing. An electron gun assembly 5 comprising an electron source 6 is provided at the top of column 2. Electron source 6 is structured to generate an electron beam 7 within column 2, which beam continues on its path into sample chamber 3, directed toward and eventually impinging on the sample (or specimen) 13. SEM 1 further includes one or more condenser lenses 9 within column 2 which focus electron beam 7 of primary electrons, also called the “primary beam”, to a predetermined diameter, such that the beam intensity, i.e., the “probe current”, increases strongly with the beam diameter. The column 2 of SEM 1 also includes deflection (scanning) coils 10 and an objective lens 12, represented by its pole piece, which further focuses electron beam 7 to a small diameter, such that electron beam 7 is convergent on sample 13 at the selected working distance 11 (i.e., the distance between the bottom of the pole piece of the objective lens 12 and the surface of sample 13), such sample 13 being positionable in several axes (usually X-Y-Z-Tilt-Rotation), by virtue of a sample stage (or specimen holder) 14. Scanning coils 10 deflect electron beam 7 and create the raster scan in the X-Y axis on the surface of sample 13. In the illustrated embodiment, there is also at least one Everhart Thornley (ET) detector, such as SED detector 15, entering the sample chamber 3 or the column 2 through an access port, such SED detector 15 providing electrical signals to a control system 16 (comprising suitable electronic processing circuitry), which in turn produces a secondary electron image on a display system 17.

Furthermore, an electron and photon detector (EPD) 18 according to the disclosed concept is positioned under the pole piece of objective lens 12 within sample chamber 3. EPD 18 is coupled to control system 16 by wires 34 (e.g., bias, signal, and ground wires) which pass through a vacuum feed-through 36 provided in sample chamber 3. EPD 18 is an annular segmented detector including a central opening and at least one sensor sensitive to photons and at least one sensor sensitive to electrons provided around the central opening. As such, that the primary electron beam of SEM 1 is able to pass through the central opening and the surrounding discrete electron sensors and the adjacent discrete photon sensors.

As seen in FIG. 1, SEM 1 also includes an X-ray detector 38. The intensity of a BSE signal is strongly related to the atomic number (Z) of the sample 13. Thus, in one embodiment, the BSE signal collected by EPD 18 configured to collect backscattered electrons is used to supplement the X-ray detector 38 which provides direct elemental analysis.

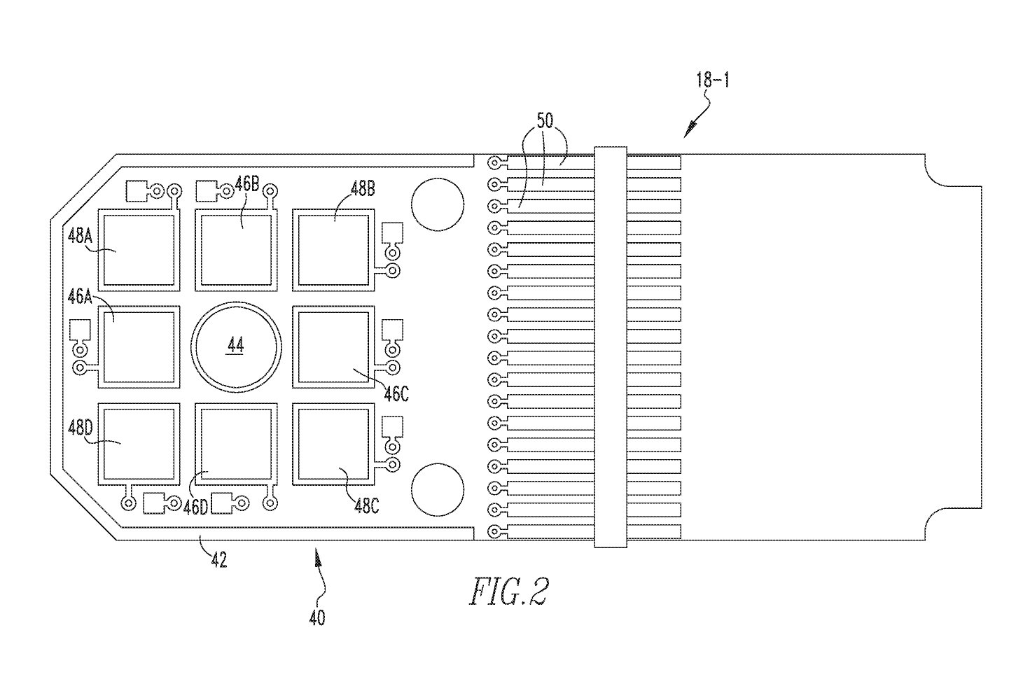

FIG. 2 is a schematic diagram of EPD detector 18-1 according to one non-limiting, exemplary embodiment. As described below, the sensors of EPD detector 18-1 employ MPPC technology and SoM technology. In particular, EPD detector 18-1 includes a printed circuit board (PCB) assembly 40 that includes a substrate 42 having a pass-through or opening 44 provided therein that is structured to allow electron beam 7 to pass through EPD 18-1 so that it can reach sample 13. In the illustrated embodiment, opening 44 is circular such that the distal end of PCB assembly 40 has a generally annular shape, but can also be square or rectangular.

As seen in FIG. 2, PCB assembly 40 includes four electron sensors 46 (labeled 46A, 46B, 46C, and 46D) positioned on the inner radius of the distal end of PCB assembly 40 and four photon sensors 48 (labeled 48A, 48B, 48C, and 48D) positioned on the outer radius of the distal end of PCB assembly 40. In the illustrated embodiment, each electron sensor 46 is an SoM sensor, such as an SiPM type SoM sensor, and each photon sensor 48 is a bare MPPC sensor, such as a bare SiPM sensor. Each electron sensor 46 and each photon sensor 48 is coupled to associated conductive traces which in turn are coupled to associated wires 50 which allow for electrical connections to be made to control system 16 as described herein such that each electron sensor 46 and each photon sensor 48 can be accessed (read-out) independently by control system 16.

As will be appreciated, BSEs are more intense as the reflection angle approaches 90°. Thus, the exemplary embodiment shown in FIG. 2 employs a configuration wherein the electron sensors 46 are placed on the inner radius and the photon sensors 48 are provided on the outer radius. It will be understood, however, that this is meant to be exemplary only, and that other configurations employing different sensor positions are contemplated within the scope of the disclosed concept. Furthermore, in the exemplary embodiment, an optically opaque coating, such as an aluminum coating, is used in EPD detector 18-1 to prevent the SoM sensors from responding to ambient light or cathodoluminescence.

In the exemplary embodiment, a single technology, such as SiPM technology, is used for both electron sensors 46 and photons sensors 48. SiPM technology provides high sensitivity, wide dynamic range, and fast recovery times (compatible with fast imaging). Although the use of photodiodes or avalanche photodiodes (APDs) instead of SiPMs is contemplated within the scope of the disclosed concept, the resulting device would be significantly slower as compared to a device implemented using SiPM technology. Also, technologies could be mixed, such as incorporating photodiodes or avalanche photodiodes with SiPMs in the device, but such a device would require the electronics to be different for the photon sensor(s) 48 (if it/they were SiPM based, for example) compared to the electron sensor(s) 46 (if it/they were APD based, for example), and would therefore likely be more complex and costly. Using SiPMs for all the sensors 46 and 48 allows the biasing and imaging electronics to be very similar, possibly identical, for all sensors 46, 48. Nevertheless, the disclosed concept contemplates the use of any solid state sensors integrated into a single, segmented detector, such that one type of sensor is sensitive to photons, and one type sensitive to electrons.

An advantage of EPD 18-1 is that it incorporates small sensors close to sample 13 for high efficiency. This is in contrast to some traditional CL detectors that place large parabolic mirrors inside the chamber. Another advantage of EPD 18-1 is that its small size minimizes interference with other detectors placed inside chamber 3. Still another advantage of EPD is that only one electrical feed-through or chamber access port 36 is required for both the BSE and CL detectors. Traditional CL detectors require a separate access port and take up valuable and limited space outside the specimen chamber as well as inside the chamber.

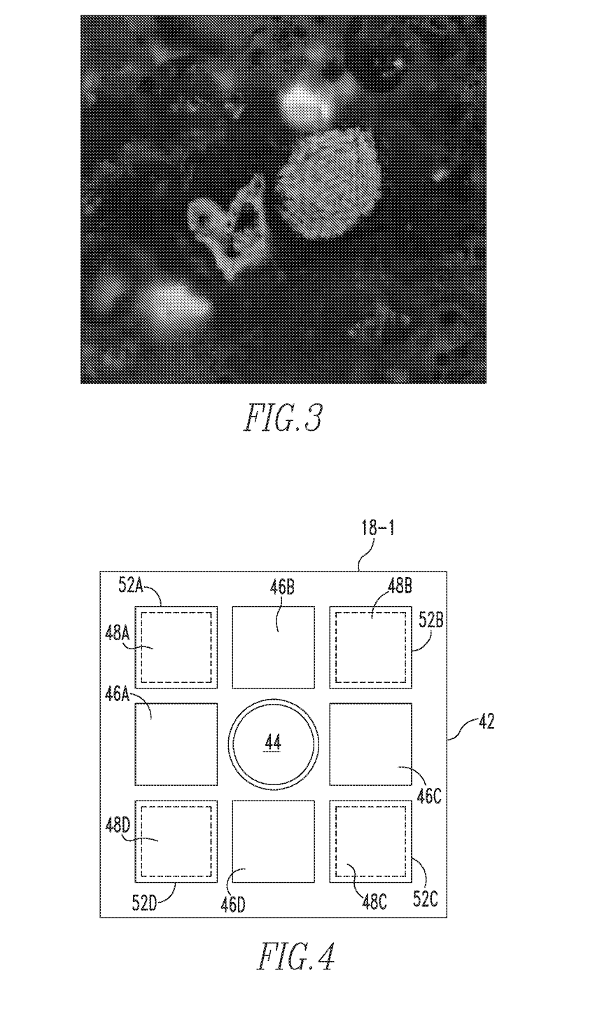

Yet another advantage of EPD 18-1 is that photon sensors 48 are segmented (as are electron sensors 46). This allows the photon emission to be viewed from photon sensors 48 having different perspectives on sample 13, and enables enhanced imaging renditions. For example, FIG. 3 is a processed image of an ore particle agglomerate collected with a prototype EPD 18-1. The image of FIG. 3 shows a strong “glowing” effect in the light emitting areas that results from the segmentation. More specifically, the processed image of FIG. 3 starts with four independent gray scale images captured by the prototype EPD 18-1. Numbering the images from 1 to 4, the source images are as follows: (1) Image 1 is generated from the sum of the outputs of photon sensor 48A with one of its nearest neighbors, e.g., photon sensor 48B; (2) Image 2 is generated from the sum of the outputs of photon sensors 48C and 48D; (3) Image 3 is the sum of the outputs of electron sensor 46A with one of its nearest neighbors, e.g., electron sensor 46B; (4) Image 4 is the sum of the outputs of electron sensors 46C and 46D. Thus, Images 1 and 2 are collected from diametrically opposite sides of opening 44, while Images 3 and 4 are electron images collected from diametrically opposite sides of opening 44. False coloring was used to render the BSE images in blue-gray and the CL images in pink. The images are then overlaid to produce the final image of FIG. 3.

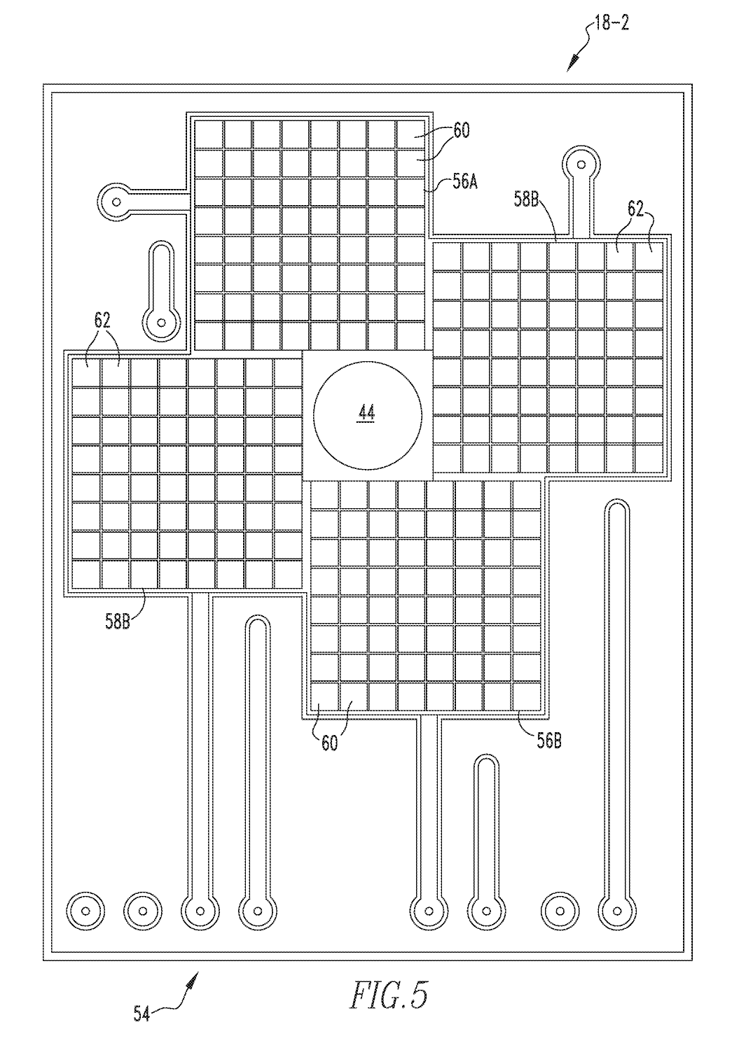

According to another embodiment, shown schematically in FIG. 4, filters 52 (labeled 52A, 52B, 52C, and 52D) can be used over discrete photon sensors 48A, 48B, 48C, and 48D to allow specific sensors to be sensitive to a spectral region of interest, with the region of interest being different for different sensors or the same for all sensors. Traditional CL detectors use spectrometers, so that the blue light, for example, can be measured or imaged uniquely from, say, red light. The use of filters 52 can produce a similar result, albeit with less range, at a much lower cost. Filters 52 can be applied as separate components, glued or otherwise attached to the surface of the associated photon sensor 48, introduced on a mechanical device such as a filter wheel, or applied to the associated photon sensor 48 as part of or subsequent to the lithography process. Utilizing one or another of these techniques, one or more photon sensors 48 can be permanently or temporarily “tuned” to specific to regions of the spectrum. For example, one photon sensor 48, or set of photon sensors 48, could be permanently or temporarily configured to detect blue light, while another detects red, and still another detects green.

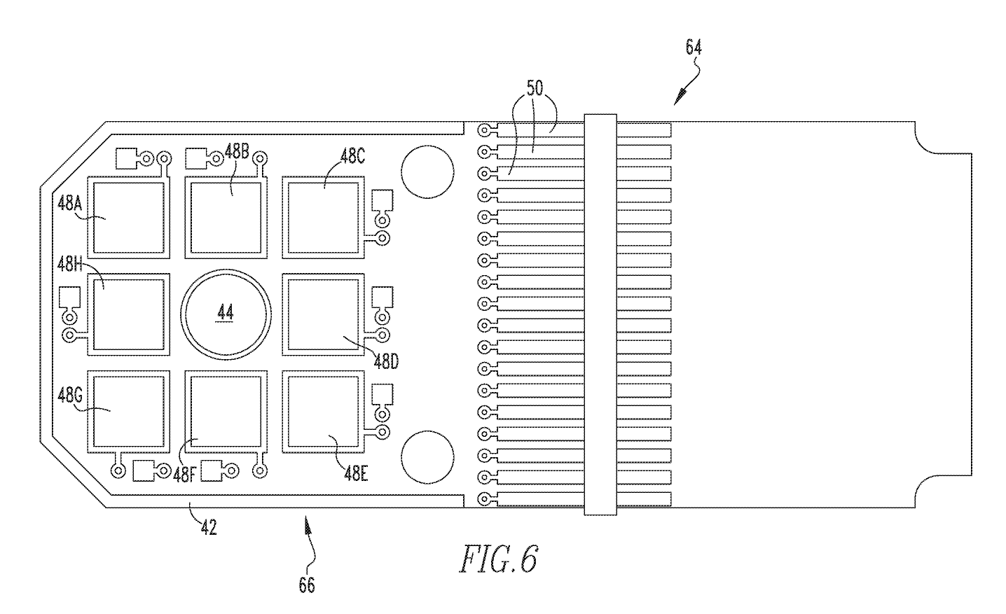

The disclosed concept may also employ arrays of MPPCs and SoMs rather than single MPPC and SoM chips. This is illustrated in FIG. 5, which is a schematic diagram of an EPD 18-2 according to an alternative embodiment. As seen in FIG. 5, EPD 18-2 includes a PCB assembly 54 having first and second electron sensor arrays 56A and 56B, and first and second photon sensor arrays 58A and 58B. First and second electron sensor arrays 56A and 56B each include an array of individual SoMs 60, such as SiPM type SoMs, and first and second photon sensor arrays 58A and 50B each include an array of individual bare MPPCs 62, such as bare SiPMs. In one exemplary embodiment, EPD 18-2 would have a thickness of between 3 and 6 mm, more preferably between 4 and 5 mm, in order to provide enhanced stiffness and support for the arrays 56 and 58.

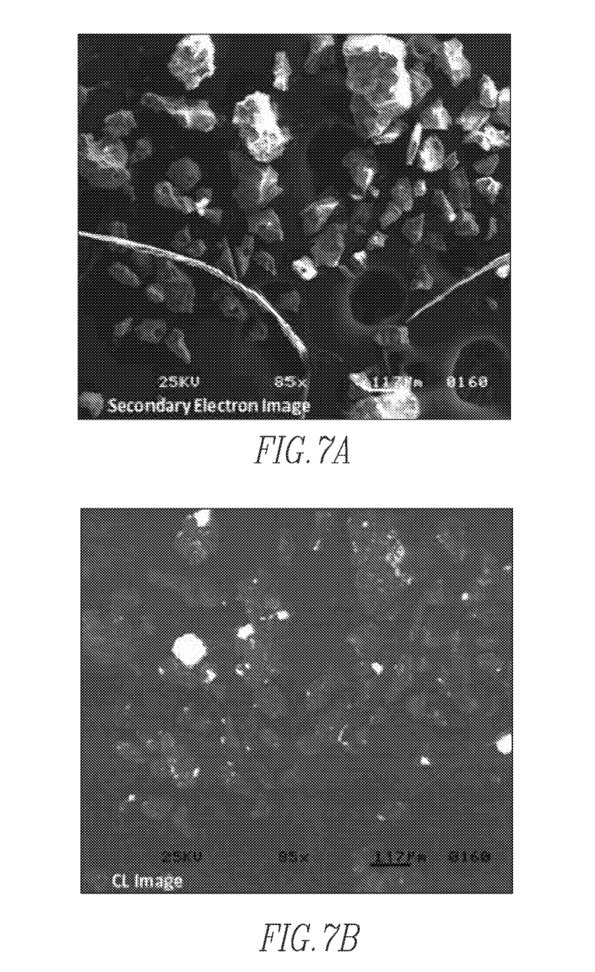

FIG. 6 is a schematic diagram of a photon detector 64 according to a further alternative exemplary embodiment. Photon detector 64 is similar to EPD detector 18 and may be used in place of EPD detector 18 in FIG. 1. Photon detector 64, however, includes a PCB assembly 66 wherein all of the sensors are photon sensors 48 as described herein (labeled 48A-48H). As such, photon detector 64 provides a compact and segmented CL detector. In this embodiment, filters 52 may be used in connection with one or more of the photon sensors 48 as described herein.

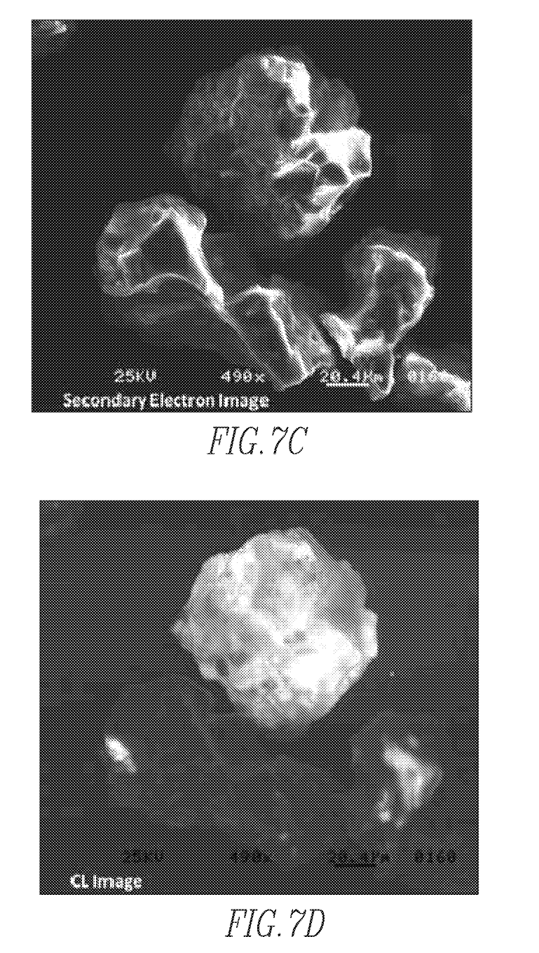

FIGS. 7A-7D provide a comparison of standard SED images to CL images captured using the prototype EPD 18. In particular, the images in FIGS. 7A and 7C are secondary electron images captured using a standard SEM detector while the images in FIGS. 7B and 7D were captured using the prototype EPD 18. Note that in the CL images of FIGS. 7B and 7D, a faint electron image appears. This is because a bare MPCC was used for photon detection, without any coating to absorb electrons. This is a benefit from the ability of a bare MPPC to produce an electron image. The value of this is that the outline of the regions of the sample which do not emit light provides an exact location of the light emitting areas in the context of the overall sample. If no electron image is wanted, a relatively thick layer of an electrically conductive but optically transparent coating like ITO can be used to eliminate the electron signal.

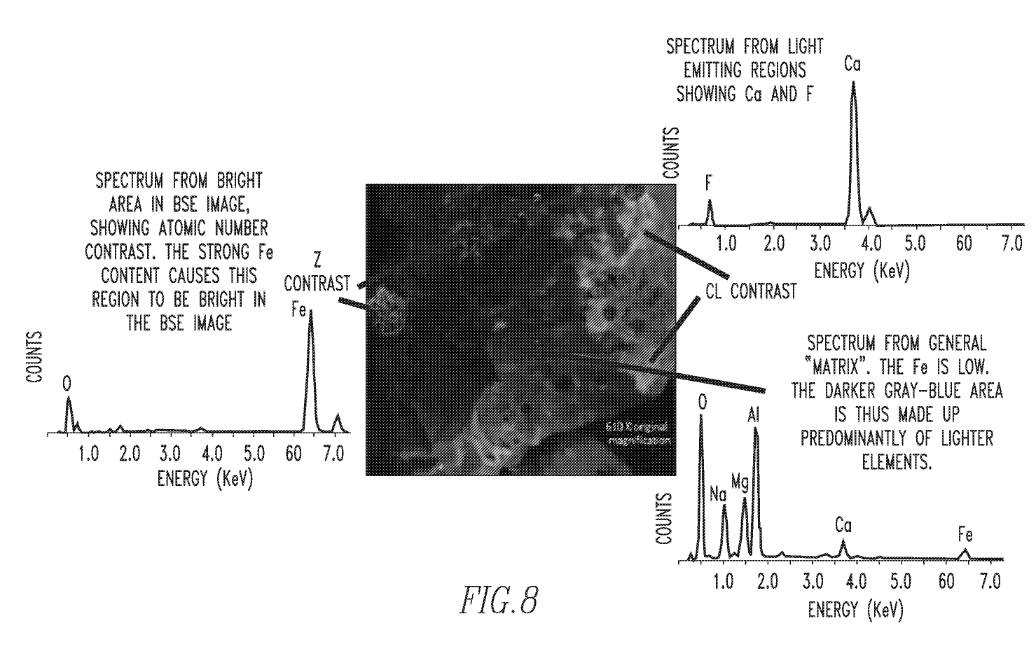

FIG. 8 is a schematic representation of an overlay image of an ore particle agglomerate produced in the manner of FIG. 3 with the prototype EPD 18 showing BSE and CL images. Energy Dispersive X-ray (EDX) analysis shows that the cluster of bright particles pointed out on the left side of the image is Fe-rich compared to the matrix, which is predominantly silicon, aluminum, sodium and oxygen (spectrum in the lower right of FIG. 8). Since the Fe-rich cluster is of higher average atomic number compared to the matrix, it appears bright in the image, showing conventional atomic number contrast of BSE imaging. EDX analysis of the bright areas pointed out on the right side of the image shows them to be rich in Ca and F. As calcium fluoride is a known CL emitter, the brightness in this case is due to light emission. Although the image of FIG. 8 was collected in a sequential manner and colorized according to the method explained in connection with FIG. 3 for maximum visual effect and information content, a single gray scale image can be collected from the sum of all sensors showing both contrast mechanisms acting simultaneously.

Furthermore, it is a known problem in cathodoluminescence imaging that many cathodoluminescent materials continue to glow after the electron beam is removed. This is known as persistent luminescence or phosphorescence. Known remedies for this problem include very long pixel dwell times, from hundreds of microseconds to a few milliseconds, interpixel delay, which allows the persistent emission to decay between pixels, and using short wavelengths only, which tend to decay faster. Each of these known remedies, however, has a disadvantage associated therewith. Long dwell times result in very slow imaging and contribute to possible charging effects on the electron-imaging side since many minerals are non-conductive. Interpixel delay is often not long enough for complete decay of the persistence. Using only short wavelengths greatly reduces the usable fraction of the information available from the CL technique.

A further aspect of the disclosed concept provides an improved solution to the persistent luminescence or phosphorescence problem. In particular, in this aspect of the disclosed concept, the high speed imaging afforded by SiPM technology (relative to other solid-state detectors like APDs) is used in conjunction with beam blanking technology to allow measurement and time-lapse imaging of the rate-of-decay of the emissions across the imaged region of a sample. A beam blanker is a well-known device that allows for the temporary deflection (typically in about 50 nS) of the electron beam off the specimen in an SEM. Such timing is a good match to the SiPM recovery time of about 100 nS or so.

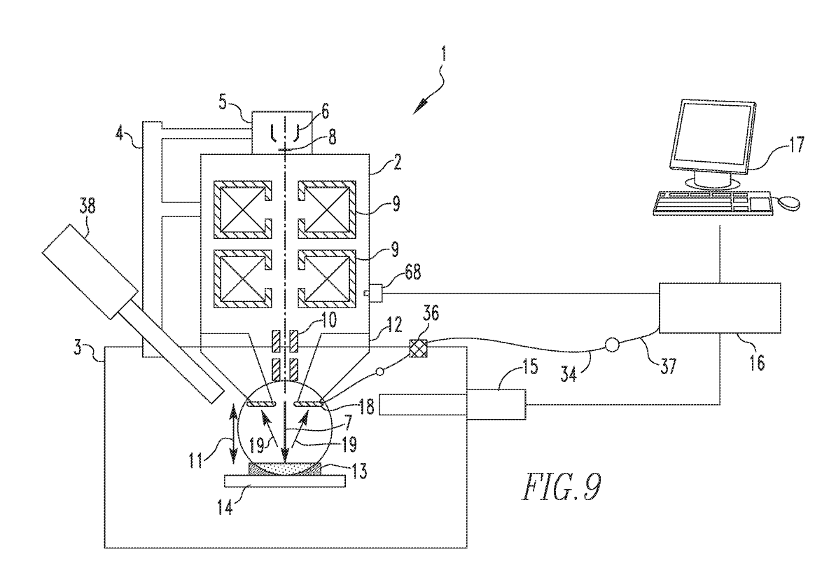

FIG. 9 is a schematic diagram of an SEM 1′ according to an alternative exemplary embodiment in which this further aspect of the disclosed concept may be implemented. SEM 1′ includes many of the same parts as SEM 1, and like parts are labeled with like reference numerals. SEM 1′ further includes a beam blanker 68 that is operatively coupled to electron column 2 and control system 16. Beam blanker 68 may be any known or hereafter beam blanking device such as, without limitation, the PCD beam blanker commercially available from Deben UK Limited.

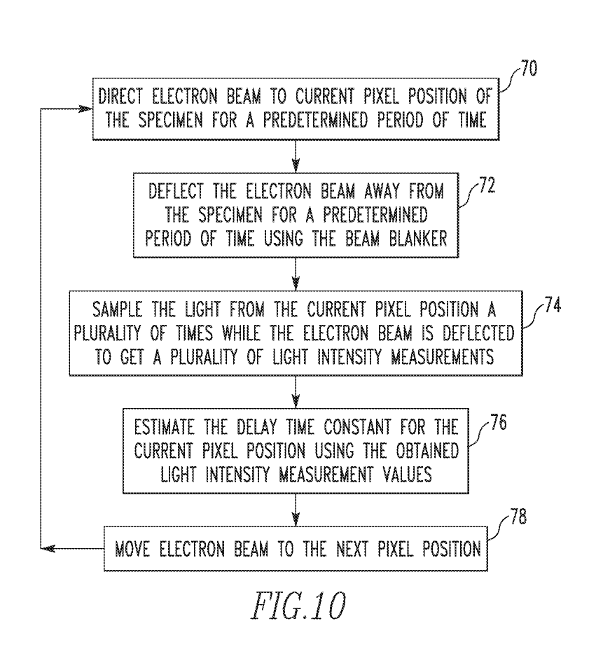

FIG. 10 is a flowchart illustrating one particular embodiment of the method of this further aspect of the disclosed concept as implemented in SEM 1′. In the exemplary embodiment, control system 16 includes a non-transitory computer readable medium, such as a non-volatile memory, that stores one or more programs having instructions for implementing the method shown in FIG. 10. As seen in FIG. 10, the method begins at step 70, wherein electron beam 7 is directed at the current pixel position of specimen 13 for a predetermined period of time. Next, at step 72, electron beam 7 is deflected away from specimen 13 for a predetermined period of time using beam blanker 68. Then, at step 74, light from the current pixel position is sampled a plurality of times using any of the detector embodiments (that include one or more photon detectors 48) described herein while electron beam 7 is deflected in order to get a plurality of light intensity measurements while the cathodoluminescence is decaying. In the exemplary embodiment, light is sampled for a few to a few 10's of microseconds after electron beam 7 is removed. In the present method, it is not necessary to wait for the light to decay entirely. Rather, all that is needed is enough of the decay curve to estimate the exponential time constant of the decay for the current pixel position. The fast response of photon detectors 48 of (which are MPPC type sensors such as bare SiPMs) allows for the light decay of specimen 13 to be distinguished from the signal decay of photon detectors 48 as long as at least 10 or so detector (e.g., SiPM) measurements and associated decay times (a microsecond or so) are obtained. In this aspect of the disclosed concept, the decay image can be collected in roughly the same time as current “fast mapping” X-ray systems, with dwell times of 10 to 100 uS.

Next, the method moves to step 76. At step 76, the decay time constant for the current pixel position is estimated in control system 16 using the obtained light intensity measurement values. Then, at step 78, electron beam 7 is moved to the next pixel position and the method returns to step 70 to repeat the process for the next pixel position. The method of FIG. 10 will be repeated until measurements are made for each pixel position of specimen 13.

Once an image of decay time constants per pixel is obtained as just described, the decay time constants per pixel can then be used in subsequent operation of SEM 1′ to compute the contribution of previous pixels in a scan to the light detected at the pixel currently illuminated by electron beam 7. The sum of contributions from the current pixel and those prior pixels whose contributions are still significant can be deconvolved using any of a number of well-known software image restoration algorithms as a post-image-collection processing step. For example, the iterative Richardson-Lucy (R-L) algorithm was revived when the Hubble Space Telescope was discovered to have spherical aberration. R-L does not require the point spread function (equivalent to the smearing caused by persistent luminescence) to be the same at all pixels, which many Fourier-space methods require. R-L is now commercially available in a number of consumer astrophotography software packages. The deconvolution causes all light emitted by a single pixel to be restored to that pixel, eliminating the blurring effect of fast scanning. Because of the scanned nature of SEM electron imaging, the blurring from persistent luminescence is one-dimensional (along the scan line) rather than two-dimensional as in conventional image restoration.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

1. A detector (18) for a charged particle beam device (1, 1′), comprising:
a substrate (42) structured to be mounted within the charged particle beam device;
a number of first sensor devices (46) provided on the substrate, wherein each of the first sensor devices is structured to be sensitive to and generate a first signal in response to electrons ejected by a specimen; and
a number of second sensor devices (48) provided on the substrate, wherein each of the second sensor devices is structured to be sensitive to and generate a second signal in response to photons emitted by the specimen.

2. The detector according to claim 1, wherein the detector is a segmented detector such that each of the first sensor devices and the second sensor devices is discrete and independently accessible.

3. The detector according to claim 1, wherein the number of first sensor devices is a plurality of first sensor devices and the number of second sensor devices is a plurality of second sensor devices.

4. The detector according to claim 1, wherein one or more of the first sensor devices comprises a MultiPixel Photon Counter device.

5. The detector according to claim 1, wherein one or more of the second sensor devices comprises a MultiPixel Photon Counter device.

6. The detector according to claim 1, wherein one or more of the first sensor devices and one or more of the second sensor devices comprise a MultiPixel Photon Counter device.

7. The detector according to claim 6, wherein the one or more of the first sensor devices each comprise a Scintillator-on-photoMultiplier device (SoM device) and the one or more of the second sensor devices each comprise a bare MultiPixel Photon Counter device.

8. The detector according to claim 7, wherein the one or more of the first sensor devices each comprise an SiPM SoM device and the one or more of the second sensor devices each comprise a bare SiPM device.

9. The detector according to claim 7, wherein the substrate includes a pass-through (44) extending through the substrate for allowing a beam of the charged particle beam device to pass through the detector, and wherein the number of first sensor devices are four first sensor devices spaced about the pass-through along an inner radius relative to the pass-through and the number of second sensor devices are four first sensor devices spaced about the pass-through along an inner radius relative to the pass-through.

10. The detector according to claim 7, wherein each SoM device includes an optically opaque coating to prevent the SoM device form responding to light.

11. The detector according to claim 1, wherein the substrate includes a pass-through (44) extending through the substrate for allowing a beam of the charged particle beam device to pass through the detector, and wherein the number of first sensor devices and the number of second sensor devices are spaced about the pass-through.

12. The detector according to claim 6, wherein the one or more of the first sensor devices each comprise an array of SoM devices and the one or more of the second sensor devices each comprise an array of bare MultiPixel Photon Counter devices.

13. The detector according to claim 1, wherein one or more of the number of second sensor devices each includes a filter.

14. The detector according to claim 13, wherein a plurality of the number of second sensor devices each includes a filter.

15. The detector according to claim 14, wherein each filter causes the second sensor devices to be sensitive to the same spectral region.

16. The detector according to claim 15, wherein the filters cause the second sensor devices to be sensitive to different spectral regions.

17. A charged particle beam device including the detector according to claim 1.

18. A photon detector (64) for a charged particle beam device, comprising:
a substrate (42) structured to be mounted within the charged particle beam device, wherein the substrate includes a pass-through (44) extending through the substrate for allowing a beam of the charged particle beam device to pass through the photon detector; and
a plurality of photon sensor devices (48) provided on the substrate spaced about the pass-through, wherein each of the photon sensor devices is structured to be sensitive to and generate a signal in response to photons emitted by the specimen, and wherein each of the photon sensor devices comprises a MultiPixel Photon Counter device.

19. The photon detector according to claim 18, wherein the detector is a segmented detector such that each of the sensor devices is discrete and independently accessible.

20. The photon detector according to claim 18, wherein each of the photon sensor devices comprises a bare MultiPixel Photon Counter device.

21. The photon detector according to claim 20, wherein each of the photon sensor devices comprises a bare SiPM.

22. The photon detector according to claim 18, wherein each of the photon sensor devices comprises an array of bare MultiPixel Photon Counter devices.

23. A charged particle beam device including the photon detector according to claim 18.

24. A method of imaging a specimen using a charged particle beam device (1, 1′), comprising:
directing an electron beam of the charged particle beam device to a first pixel position of the specimen for a first period of time;
deflecting the electron beam away from the first pixel position for a second period of time;
measuring a plurality of light intensity levels emitted from the first pixel position during the second period of time using a detector having a number of MultiPixel Photon Counter sensors; and
using the plurality of light intensity levels to estimate a decay time constant for the first pixel position.

25. The method according to claim 24, further comprising generating an image of the specimen using a raster scan of the charged particle beam device and at least the decay time constant for the first pixel position.

26. The method according to claim 24, further comprising repeating the directing, deflecting, measuring and using steps for a plurality of additional pixel positions to estimate a decay time constant for each of the additional pixel positions.

25. The method according to claim 26, further comprising generating an image of the specimen using a raster scan of the charged particle beam device and the decay time constant for the first pixel position and the decay time constant for each of the additional pixel positions.

28. The method according to claim 24, further comprising detecting light emitted from a second pixel position different than the first pixel position during a raster scan of the charged particle beam and computing a contribution of the first pixel position during the raster scan to the light detected from the second pixel position using the decay time constant for the first pixel position.

29. The method according to claim 24, wherein the deflecting step employs a beam blanker (68).

30. A charged particle beam device (1, 1′), comprising:
an electron source (6) structured to generate an electron beam;
a beam blanker (68);
a photon detector (18, 64) including a number of MultiPixel Photon Counter sensors (48); and
a control system (16) structured to:
cause the electron beam to be directed to a first pixel position of the specimen for a first period of time;
cause the beam blanker to deflect the beam away from the first pixel position for a second period of time;
cause the detector to measure a plurality of light intensity levels emitted from the first pixel position during the second period of time; and
use the plurality of light intensity levels to estimate a decay time constant for the first pixel position.

31. The charged particle beam device according to claim 30, wherein the control system is structured to generate an image of the specimen using a raster scan of the charged particle beam device and at least the decay time constant for the first pixel position.

32. The charged particle beam device according to claim 30, wherein the control system is structured to:
cause the electron beam to be directed to a plurality of additional pixel positions of the specimen each for an additional first period of time;
cause the beam blanker to deflect the beam away from each additional first pixel position for an additional second period of time;
cause the detector to measure a plurality of additional light intensity levels emitted from each additional first pixel position during each second period of time; and
use the plurality of additional light intensity levels to estimate a decay time constant for each of the additional pixel positions.

33. The charged particle beam device according to claim 32, wherein the control system is structured to generate an image of the specimen using a raster scan of the charged particle beam device and the decay time constant for the first pixel position and the decay time constant for each of the additional pixel positions.

34. The charged particle beam device according to claim 30, wherein the control system is structured to detect light emitted from a second pixel position different than the first pixel position during a raster scan of the charged particle beam and compute a contribution of the first pixel position during the raster scan to the light detected from the second pixel position using the decay time constant for the first pixel position.

35. A non-transitory computer readable medium storing one or more programs, including instructions, which when executed by a computer, causes the computer to perform the method of claim 24.
